(19) United States
(12) Patent Application Publication
(10) Pub. No.: US 2015/0044619 A1
(43) Pub. Date: Feb. 12, 2015

(54) Carrier for Ultra-Thin Substrates and Method of Use

(71) Applicant: International Business Machines Corporation, Armonk, NY (US)

(72) Inventors: John C. Hall, New Hartford, CT (US); Jeffrey C. Maling, Grand Isle, VT (US); Charles F. Musante, Burlington, VT (US)

(73) Assignee: INTERNATIONAL BUSINESS MACHINES CORPORATION, Armonk, NY (US)

(21) Appl. No.: 13/961,208

(22) Filed: Aug. 7, 2013

(51) Int. Cl. H01L 21/673; B65D 21/02

(52) U.S. Cl. CPC H01L 21/67346; B65D 21/0212
USPC 432/9; 248/346.01; 294/172; 414/800

(57) ABSTRACT

A substrate carrier, including: a baffle having a continuous perimeter sidewall surrounding an enclosed region; and one or more standoffs attached to an inside surface of the perimeter sidewall, the one or more standoffs extending into the enclosed region and below a bottom edge of the perimeter sidewall, the one or more standoffs each having a lip located between an upper edge of the baffle and the lower edge of the baffle. Also, a method of annealing substrates using the substrate carrier.

### TECHNICAL FIELD

The present invention relates to the field of integrated circuit technology; more specifically, it relates to a carrier of ultra-thin substrates and a method of fabricating integrated circuits using the carrier.

### BACKGROUND

Handling ultra-thin substrates is highly problematic in a manufacturing environment, especially as product requirements drive manufacturers to produce ever thinner semiconductor chips. One problem associated with processing ultra-thin substrates is breakage. Ultra-thin substrates are extremely fragile. For example, in processes that require flowing gases in/around thin substrates breakage of the ultra-thin substrates is a continuing problem. Accordingly, there exists a need in the art to mitigate the deficiencies and limitations described hereinabove.

### BRIEF SUMMARY

A first aspect of the present invention is a substrate carrier, comprising: a baffle having a continuous perimeter sidewall surrounding an enclosed region; and one or more standoffs attached to an inside surface of the perimeter sidewall, the one or more standoffs extending into the enclosed region and below a bottom edge of the perimeter sidewall, the one or more standoffs each having a lip located between an upper edge of the baffle and the lower edge of the baffle.

A second aspect of the present invention is a method, comprising: placing a lift block on a work surface; providing a substrate carrier comprising: a baffle having a continuous perimeter sidewall surrounding an enclosed region; and one or more standoffs attached to an inside surface of the perimeter sidewall, the one or more standoffs extending into the enclosed region and below a bottom edge of the perimeter sidewall, the one or more standoffs each having a lip located between an upper edge of the baffle and the lower edge of the baffle; placing the substrate carrier on the work surface over the lift block, a top surface of the lift block extending above the top edge of the perimeter sidewall relative to the surface; placing a semiconductor substrate on a substrate carrier and placing carrier plate on the top surface of the lift block; lifting the substrate carrier from the lift block; and after the lifting the substrate carrier resting on the lips of the one or more standoffs, the wafer contained within the enclosed region.

These and other aspects of the invention are described below.

### BRIEF DESCRIPTION OF THE DRAWINGS

The features of the invention are set forth in the appended claims. The invention itself, however, will be best understood by reference to the following detailed description of illustrative embodiments when read in conjunction with the accompanying drawings, wherein:

FIG. 1A is a top view and FIG. 1B is a cross-section view thru line 1B-1B of FIG. 1A of a substrate carrier according to embodiments of the present invention;

FIG. 2 is a detailed view of FIG. 1B;

FIG. 3 illustrates stacking substrate carriers according to embodiments of the present invention;

FIG. 4A is a top view and FIG. 4B is a cross-section view thru line 4B-4B of FIG. 4A of a substrate carrier according to alternative embodiments of the present invention;

FIG. 5 illustrates stacking alternative substrate carriers according to embodiments of the present invention;

FIG. 6 is a cross-section of an alternative baffle that may be used in any of the substrate carriers according to embodiments of the present invention;

FIG. 7 is a cross-section through a substrate carrier that incorporates a vacuum chuck according to embodiments of the present invention; and

FIGS. 8A through 8E illustrate a method of annealing ultra-thin substrates using substrate carriers according to embodiments of the present invention.

### DETAILED DESCRIPTION

Integrated substrates are comprised of semiconductor material (e.g., silicon), are usually circular and are often referred to as wafers. Multiple integrated circuit chips may be fabricated on a single wafer. A typical ultra-thin semiconductor wafer is about 200 mm in diameter and about 100 microns thick or less (compared to about 725 microns for a non-thinned wafer). Ultra-thin wafers of 300 mm and 450 mm diameters as well as ultra-thin wafers as thin as 40 micron thick are contemplated. These ultra-thin wafers are easily bowed and if bowed too much will fracture and break. It has been found that when placed in a process tool that flow gas over ultra-thin wafers, the edges of the ultra-thin wafers can be picked up by Bernoulli forces and the ultra-thin wafers broken. To avoid this, ultra-thin wafers are adhesively bonded to thicker handle substrates. However, if the process requires heating to about 250° C. or greater, the adhesive will break-down and the ultra-thin wafers subsequently break.

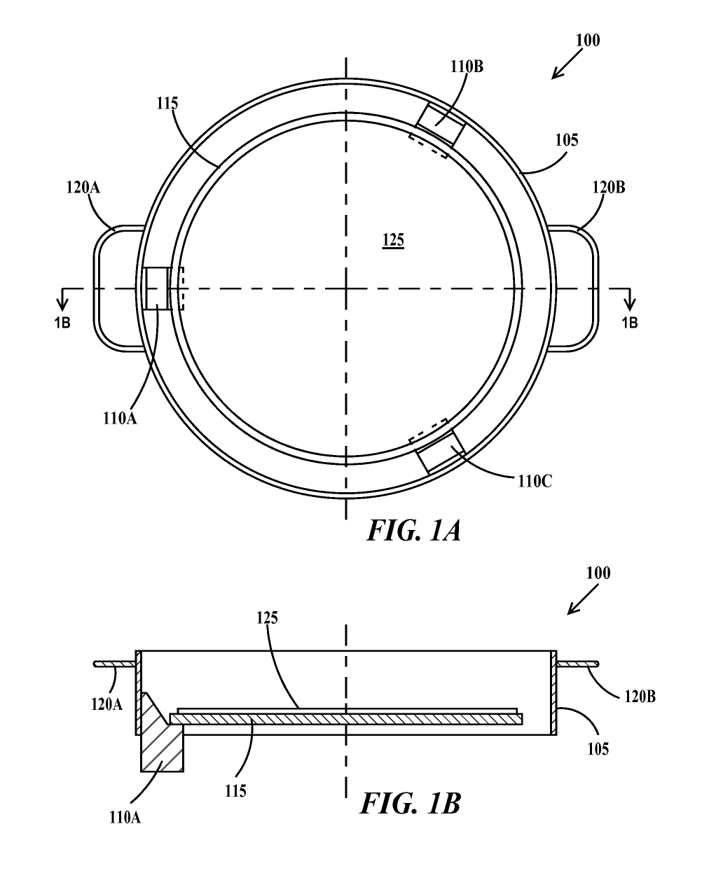

FIG. 1A is a top view and FIG. 1B is a cross-section view thru line 1B-1B of FIG. 1A of a substrate carrier according to embodiments of the present invention. In FIGS. 1A and 1B, a substrate carrier 100 comprises a baffle 105 having a continuous perimeter side wall, three identical and equally spaced standoffs 110A, 110B and 110C attached to the inside sidewall of baffle 105, a non-attached carrier plate 115 resting on standoffs 110A, 110B and 110C and optional handles 120A and 120B attached to the outside sidewall of baffle 105. In the example of FIGS. 1A and 1B, baffle 105 is a thin-walled cylinder. Handles 120A and 120B and standoffs 110A, 110B and 110C may be attached to baffle 105 by screws or rivets or may be welded to baffle 105. Standoffs 110A, 110B and 110C only extend part way from the inside of baffle 105 toward the geometric center of baffle 105. Carrier plate 115 is required with ultra-thin substrates that are defined as substrates that are flexible to the extent that they will sag in their middles under their own weight when only supported by their edges. Light and stiff substrates do not require a standoff plate. A stiff and light substrate is defined as a substrate that can be easily moved by a gas flow passing directly across the surface of the substrate but does not sag in the middle when supported only by its edges. A Styrofoam plate is an example of a light and stiff substrate. An ultra-thin substrate 125 (i.e., a substrate having a thickness of 100 microns or less), which is an example of a flexible substrate, is illustrated resting on (not bonded) or otherwise attached to carrier plate 115. In one example, ultra-thin substrate 125 is an ultra-thin semiconductor wafer having a diameter between about 100 mm and about 450 mm and a thickness of between about 100 microns and about 40 microns. Carrier plate 115 may be fabricated from glass, metal, ceramic or a non-thinned semiconductor wafer. Carrier plate 115 may be a solid disk, a disk having perforations or a wire mesh disk. It is advantageous that carrier plate 115 have a flat surface for the substrate to rest on. Materials for baffle 105 and standoffs 110A, 110B and 110C include stainless steel, aluminum or other metals. While three standoffs 110A, 110B and 110C are illustrated, there may be N-standoffs, where N is an integer of three or more.

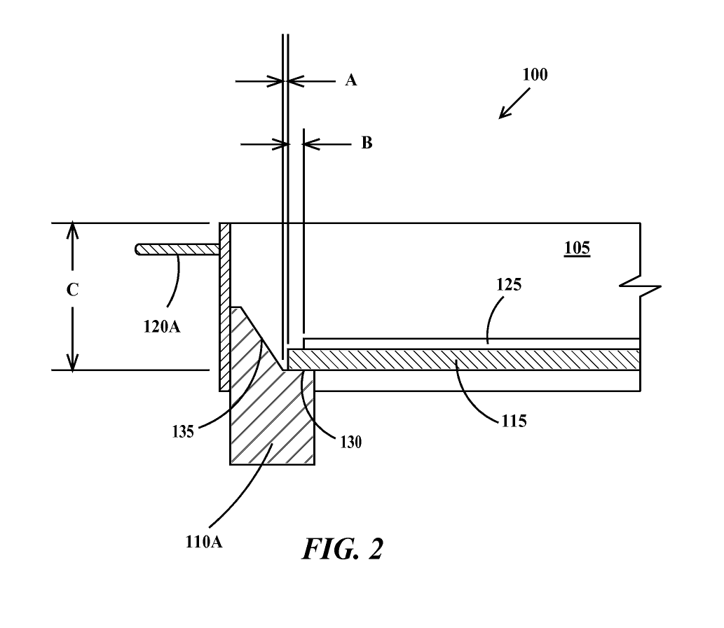

FIG. 2 is a detailed view of FIG. 1B. In FIG. 2, standoff 110A includes a lip region 130 and a sloped region 135 positioned within baffle 105. Carrier 115 rests on lip region 130 and is separated from sloped region by a distance “A.” An edge of substrate 125 is separated from an edge of carrier 115 by a distance “B.” Thus the diameter of carrier is equal to the diameter of substrate 125 plus two times the value of “B.” Baffle 105 has a height “C” above lip 130. In one example, for a 200 mm diameter substrate “A” is about 2 mm, “B” is about 6 mm and carrier 115 has a diameter of about 212 mm. In one example, “C” is selected so gas flowing across the top of baffle 105 will not pick up substrate 125 by Bernoulli forces. In one example, for a 200 mm diameter semiconductor wafer “C” is at least 25 mm.

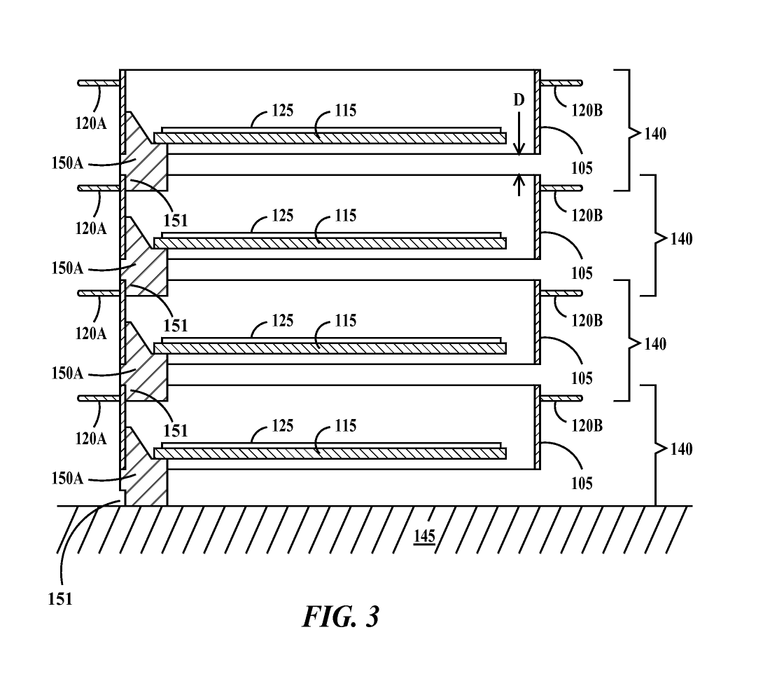

FIG. 3 illustrates stacking substrate carriers according to embodiments of the present invention. In FIG. 3, four substrate carriers 140 are stacked on a surface 145. Substrate carriers 140 are similar to substrate carrier 100 of FIGS. 1A and 1B except standoffs 110A, 110B and 110C of FIGS. 1A and 1B are replaced with standoffs 150A, 150B and 150C respectively (only standoffs 150A are illustrated in FIG. 3). The difference between standoffs 110A, 110B and 110C and standoffs 150A, 150B and 150C is standoffs 150A, 150B and 150C include notches 151 that will engage the bottom regions of baffles 105.

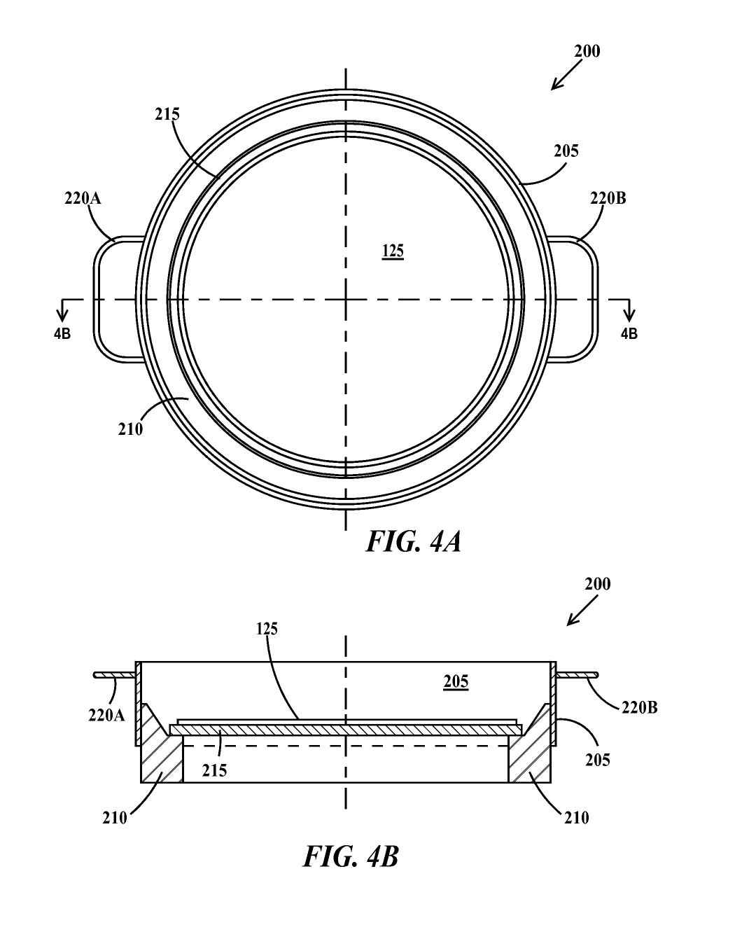

FIG. 4A is a top view and FIG. 4B is a cross-section view thru line 4B-4B of FIG. 4A of a substrate carrier according to alternative embodiments of the present invention. In FIGS. 4A and 4B, a substrate carrier 200 comprises a cylindrical baffle 205, an annular ring shaped standoff 210 attached to the inside sidewall of baffle 205, a non-attached carrier plate 215 resting on standoff 210 and optional handles 220A and 220B attached to the outside sidewall of baffle 205. Ultra-thin substrate 125 is illustrated resting on (not bonded or otherwise attached to carrier plate 215. Carrier plate 215 may be fabricated from glass, metal, ceramic or a non-thinned semiconductor wafer. Materials for baffle 205 and standoff 210 include stainless steel and aluminum

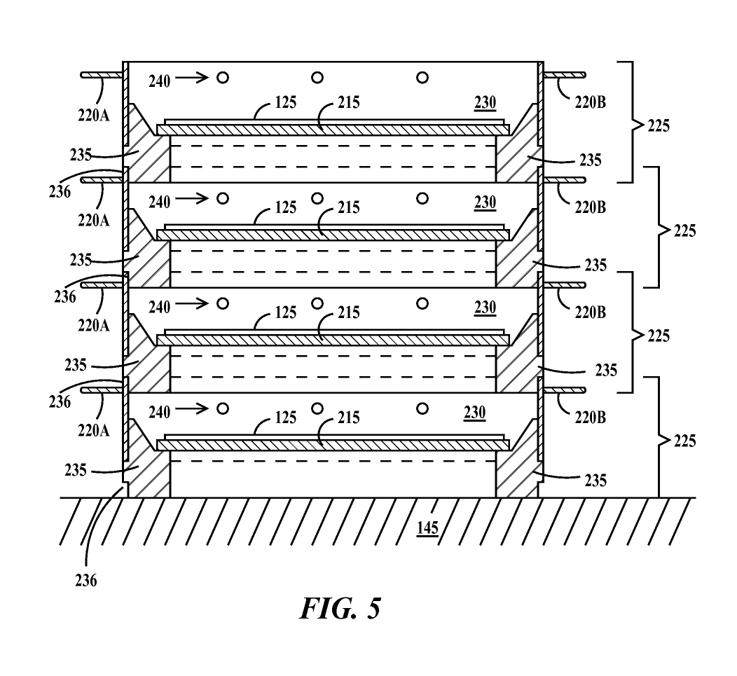

FIG. 5 illustrates stacking alternative substrate carriers according to embodiments of the present invention. In FIG. 5, four substrate carriers 225 are stacked on surface 145. Substrate carriers 225 are similar to substrate carrier 200 of FIGS. 4A and 4B except baffle 210 of FIGS. 4A and 4B is replaced with baffle 230 and standoff 210 of FIGS. 3A and 3B is replaced with standoff 235. The difference between standoff 210 and standoff 235 is standoff 235 includes a circular notch 236 that will engage the bottom regions of baffles 230. Baffles 230 are illustrated with a small number of optional perforations 240 that allow ambient atmosphere to fill the volume between the top surface of a lower substrate 125 and a bottom surface of a higher standoff plate. In one example, perforations 240 account for less than about 10% of the surface areas of baffles 230.

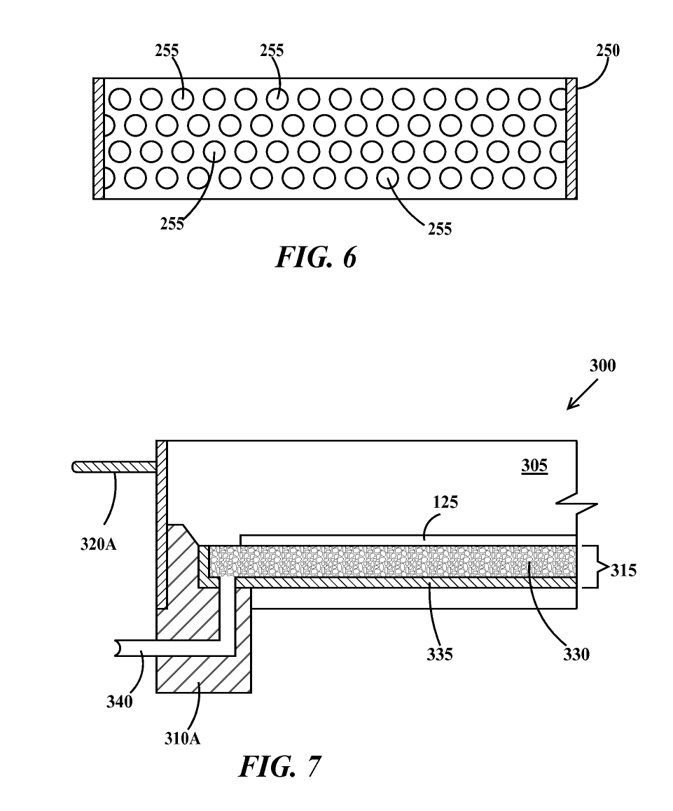

FIG. 6 is a cross-section of an alternative baffle that may be used in any of the substrate carriers according to embodiments of the present invention. In FIG. 6, a baffle 250 includes a large number of circular perforations 255 that allow a reduced gas flow over substrate 125 (see FIGS. 1A and 1B or 4A and 4B) such that the Bernoulli effect is reduced so substrate 125 cannot be lifted by the gas flow. In one example, perforations 255 account for between about 25% and about 75% of the surface area of baffle 250.

FIG. 7 is a cross-section through a substrate carrier that incorporates a vacuum chuck according to embodiments of the present invention. In FIG. 7, a substrate carrier 300 comprises a cylindrical baffle 305, three identical and equally spaced standoffs 310A, 310B and 310C (only standoff 310A is illustrated) similarly to standoffs 110A, 110B and 110C of FIG. 1A that are attached to the inside sidewall of baffle 305, a vacuum chuck 315 that serves as a wafer carrier resting on or attached to standoffs 310A, 310B and 310C and optional handles 320A and 320B attached to the outside sidewall of baffle 305. Vacuum chuck 315 may be fabricated from sintered aluminum or any porous metal or ceramic material. In FIG. 7, vacuum chuck 315 includes a porous core 330 surrounded on the sides and bottom with a no permeable liner 335. A vacuum line 340 connects to core 330. Materials for baffle 305 and standoffs 310A, 310B and 310C include stainless steel and aluminum.

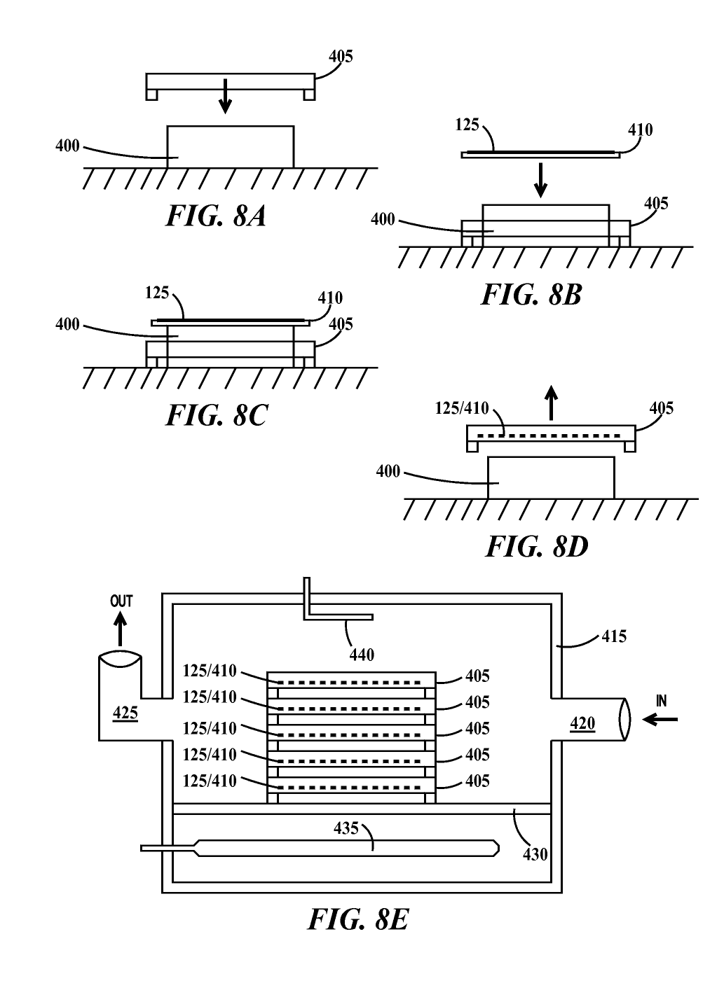

FIGS. 8A through 8E illustrate a method of annealing ultra-thin substrates using substrate carriers according to embodiments of the present invention. In FIG. 8A, a lift block 400 is provided and a substrate carrier 405 is lowered over lift block 400. In FIG. 8B, with both lift block 400 and carrier 405 resting on the same surface, the top surface of the lift block 400 is raised above substrate carrier 405. A substrate 125 resting on but not bonded or otherwise attached to a carrier 410 is lowered onto lift block 400. FIG. 8C illustrates the substrate/carrier combination 125/410 resting on lifting block 400. In FIG. 8D, substrate carrier 405 is lifted off lifting block 400 and the substrate/carrier combination 125/410 (dashed line) is captured by substrate carrier 405 similar to the position of substrate 125 and carrier 115 of FIG. 1B. Carrier 405 represents any of the carrier embodiments described supra. In FIG. 8E, a series of substrate/carrier combination 125/410 have been stacked in an annealing oven 415. In one example, substrates 125 are ultra-thin semiconductor substrates having a thickness of 100 microns or less and containing integrated circuit chips that are to be annealed at temperatures of greater than about 250° C. Annealing oven 415 includes a gas input port 420 and a gas output port 425, a shelf 430, a heater 435 and a temperature sensor 440. In one example, substrates 125 are ultra-thin semiconductor substrates containing integrated circuit chips that are to be annealed at temperatures of greater than about 250° C. and the annealing gas is nitrogen or a nitrogen/hydrogen mixture. For stiff and light substrates, the substrate carrier 410 may be eliminated.

Though the present invention has been described using semiconductor substrates which are circular and a circular substrate carrier, substrate carriers of the embodiments of the present invention may be used for any ultra-thin substrate, such as glass, plastic, metal or ceramic substrates and are not limited to being circular, but may be n-sided (with n being an integer equal to or greater than 3) and/or shaped to conform to the circumference of the substrate.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A substrate carrier, comprising:
a baffle having a continuous perimeter sidewall surrounding an enclosed region; and
one or more standoffs attached to an inside surface of said perimeter sidewall, said one or more standoffs extending into said enclosed region and below a bottom edge of said perimeter sidewall, said one or more standoffs each having a lip located between an upper edge of said baffle and said lower edge of said baffle.

2. The substrate carrier of claim 1, further including a removable carrier plate configured to rest on said lips of said one or more standoffs within said enclosed region.

3. The substrate carrier of claim 2, wherein said baffle is cylindrical and said carrier plate is a flat disk.

4. The substrate carrier of claim 2, wherein said carrier plate is configured to support an ultra-thin semiconductor wafer having a thickness of 100 microns or less.

5. The substrate carrier of claim 2, wherein said carrier plate is a solid.

6. The substrate carrier of claim 2, wherein said carrier plate is a perforated.

7. The substrate carrier of claim 2, wherein said carrier plate comprises a flat wire mesh.

8. The substrate carrier of claim 2, wherein said carrier plate comprises glass, metal, ceramic or a semiconductor wafer.

9. The substrate carrier of claim 1, wherein said baffle is cylindrical and said one or more standoffs comprise a single annular ring

10. The substrate carrier of claim 1, wherein said perimeter sidewall of said baffle is perforated.

11. The substrate carrier of claim 1, wherein said baffle and said one or more standoffs independently comprise a material selected from the group consisting of aluminum, stainless steel and metal.

12. The substrate carrier of claim 1, wherein a height of said perimeter wall above said lips of said one or more standoffs is at least 25 mm.

13. The substrate carrier of claim 1, wherein each of said one or more standoffs have a sloped surface extending from a top surface of the standoff to said lip.

14. The substrate carrier of claim 1, wherein each standoff of said one or more standoffs has a notch in the region of the standoff that extends below said perimeter sidewall, said notch configured to engage an upper region of a perimeter sidewall of an additional substrate carrier when two or more substrate carriers are stacked.

15. The substrate carrier of claim 1, wherein said perimeter sidewall and said one or more standoffs are configured to prevent a flow of gas passing over a top surface substrate resting within said enclosed region from being removed from said enclosed region by said gas flow and still allow some of said gas flow to pass over said top surface of said substrate.

16. The substrate carrier of claim 1, further including two handles fastened to opposite outer surfaces of said perimeter sidewalls.

17. A method, comprising:
placing a lift block on a work surface;
providing a substrate carrier comprising:
a baffle having a continuous perimeter sidewall surrounding an enclosed region; and
one or more standoffs attached to an inside surface of said perimeter sidewall, said one or more standoffs extending into said enclosed region and below a bottom edge of said perimeter sidewall, said one or more standoffs each having a lip located between an upper edge of said baffle and said lower edge of said baffle;
placing said substrate carrier on said work surface over said lift block, a top surface of said lift block extending above said top edge of said perimeter sidewall relative to said surface;
placing a semiconductor substrate on a substrate carrier and placing carrier plate on said top surface of said lift block;
lifting said substrate carrier from said lift block; and
after said lifting said substrate carrier resting on said lips of said one or more standoffs, said semiconductor substrate contained within said enclosed region.

18. The method of claim 17, further including placing said substrate carrier in an oven having a temperature of at least 250° C. and flowing a gas over said substrate carrier.

19. The method of claim 18, further including placing an additional substrate carrier containing an addition semiconductor substrate on an additional substrate carrier on top said substrate carrier.

20. The method of claim 17, wherein said semiconductor substrate is a circular wafer having a thickness of 100 microns or less.
